(19) United States
(12) Patent Application Publication
(10) Pub. No.: US 2010/0044861 A1
(43) Pub. Date: Feb. 25, 2010

(54) SEMICONDUCTOR DIE SUPPORT IN AN OFFSET DIE STACK

(76) Inventors: Chin-Tien Chiu, Taichung City (TW); Hem Takiar, Fremont, CA (US); Jia Qing Xi, MinHang District ShangHai (CN)

Correspondence Address: VIERRA MAGEN/SANDISK CORPORATION, 575 MARKET STREET, SUITE 2500, SAN FRANCISCO, CA, 94105, US

(21) Appl. No.: 12/194,809

(22) Filed: Aug. 20, 2008

(51) Int. Cl. H01L 23/49

(52) U.S. Cl. 257/738; 257/777; 257/E23.024

(57) ABSTRACT

A semiconductor device is disclosed including a support structure for supporting an edge of a semiconductor die that is not supported on the substrate or semiconductor die below. In embodiments, the semiconductor device may in general include a substrate having a plurality of contact pads, a first semiconductor die mounted on the substrate, and a second semiconductor die mounted on the first semiconductor die in an offset configuration so that an edge of the second semiconductor die overhangs the first semiconductor die. A support structure may be affixed to one or more of the contact pads beneath the overhanging edge to support the overhanging edge during a wire bonding process which exerts a downward force on the overhanging edge.

### BACKGROUND OF THE INVENTION

1. Field of the Invention

Embodiments of the present invention relate to a low profile semiconductor device and method of fabricating same.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate in a stacked configuration. An edge view of a conventional semiconductor package 20 (without molding compound) is shown in prior art FIGS. 1 and 2. Typical packages include a plurality of semiconductor die 22, 24 mounted to a substrate 26. Although not shown in FIGS. 1 and 2, the semiconductor die are formed with die bond pads on an upper surface of the die. Substrate 26 may be formed of an electrically insulating core sandwiched between upper and lower conductive layers. The upper and/or lower conductive layers may be etched to form conductance patterns including electrical leads and contact pads. Wire bonds are soldered between the die bond pads of the semiconductor die 22, 24 and the contact pads of the substrate 26 to electrically couple the semiconductor die to the substrate. The electrical leads on the substrate in turn provide an electrical path between the die and a host device. Once electrical connections between the die and substrate are made, the assembly is then typically encased in a molding compound to provide a protective package.

It is known to layer semiconductor die on top of each other either in a stacked configuration (prior art FIG. 1) or with an offset (prior art FIG. 2). In the stacked configuration of FIG. 1, two or more semiconductor die are stacked directly on top of each other, thereby providing a minimal footprint for a given size semiconductor die. However, in a stacked configuration, space must be provided between adjacent semiconductor die for the bond wires 30. In addition to the height of the bond wires 30 themselves, additional space must be left above the bond wires, as contact of the bond wires 30 of one die with the next die above may result in an electrical short. As shown in FIG. 1, it is therefore known to provide a dielectric spacer layer 34 to provide enough room for the wire bond 30 to be bonded to the die bond pad on the lower die 24.

In the offset configuration of FIG. 2, the die are stacked with an offset so that the bond pads of the next lower die are left exposed. Such configurations are shown for example in U.S. Pat. No. 6,359,340 to Lin, et al., entitled, “Multichip Module Having a Stacked Chip Arrangement.” An offset configuration provides an advantage of convenient access of the bond pads on each of the semiconductor die. In the embodiment shown in FIG. 2, the wire bonds are formed off of the first edge of the top semiconductor die 22 and the opposite edge of the bottom semiconductor die 24. It is also known to provide the wire bonds off of the top die 22 from the same edge as the bottom die 24.

In the configurations of FIGS. 1 and 2, after the die are mounted, the die may be wire bonded between the substrate and respective die using a wire bonding capillary. One known wire bonding process is a ball bonding process, where a length of wire (typically gold or copper) to be wire bonded is fed through a central cavity of the wire bonding capillary. The wire protrudes through a tip of the capillary, where a high-voltage electric charge is applied to the wire from a transducer associated with the capillary tip. The electric charge melts the wire at the tip and the wire forms into a ball owing to the surface tension of the molten metal.

As the ball solidifies, the capillary is lowered to the surface of a semiconductor die to receive the first end of the wire bond. The surface may be heated to facilitate a better bond. The wire bond ball is deposited on a die bond pad of the die under a load, while the transducer applies ultrasonic energy. The combined heat, pressure, and ultrasonic energy create a bond between the wire bond ball and the die bond pad.

The wire is then payed out through the capillary and the wire bond device moves over to the substrate (or other semiconductor) receiving the second end of the wire bond. The second bond, referred to as a wedge or tail bond, is then formed again using heat, pressure and ultrasonic energy, but instead of forming a ball, the wire is crushed under pressure to make the second bond. The wire bonding device then pays out a small length of wire and tears the wire from the surface of the second bond. The small tail of wire hanging from the end of the capillary is then used to form the wire bond ball for the next subsequent wire bond. The above-described cycle can be repeated about 20 to 30 times per second.

As seen in FIGS. 1 and 2, the portion of the upper die 22 receiving the wire bonds overhangs the lower die 24 and is unsupported on its back surface. One problem in conventional semiconductor packages is that, when the wire bonding capillary contacts the upper die to adhere the wire bond balls, it exerts a downward pressure on the portion of the die 22 that is unsupported at its back surface. In the past, semiconductor die were thick enough that this was not a significant problem. However, as the thickness of semiconductor die has substantially decreased, the pressure exerted by the wire bond capillary during wire bonding can crack or otherwise damage the upper die.

### SUMMARY OF THE INVENTION

Embodiments of the present invention relate to a semiconductor device including a support structure for supporting an edge of a semiconductor die that is not supported on the substrate or semiconductor die below. In embodiments, the semiconductor device may in general include a substrate having a plurality of contact pads, a first semiconductor die mounted on the substrate, and a second semiconductor die mounted on the first semiconductor die in an offset configuration so that an edge of the second semiconductor die overhangs the first semiconductor die. A support structure may be affixed to one or more of the contact pads beneath the overhanging edge to support the overhanging edge during a wire bonding process which exerts a downward force on the overhanging edge.

In embodiments, the support structure on an individual contact pad may be a single support ball or a stack of support balls affixed to the contact pad using a wire bonding capillary. The height of the support ball(s) is approximately the thickness of the first semiconductor die so that the second semiconductor die rests flatly on both the first semiconductor die and the support balls. This allows the overhanging edge of the second semiconductor die to be supported during a subsequent wire bonding process so that stresses within the overhanging edge are minimized.

Instead of or in addition to support balls formed by a wire bonding capillary, bumps may be formed on a contact pad by stud bumping or gold bumping at the wafer level or at assembly process. In a further alternative embodiment, instead of a support ball, the support structure may be a wire loop, such as a balcony loop, formed between a pair of contact pads on the substrate. The wire loop supports the overhanging edge of the semiconductor die during a subsequent wire bonding process.

### DESCRIPTION OF THE DRAWINGS

FIG. 1 is a prior art edge view of a conventional semiconductor device including a pair of semiconductor die in an overlapping relation and separated by a spacer layer.

FIG. 2 is a prior art edge view of a conventional semiconductor device including a pair of semiconductor die stacked in an offset relation.

FIG. 3 is a flowchart showing the fabrication of a semiconductor device according to embodiments of the present invention.

FIG. 4 is a top view of a semiconductor device according to an embodiment of the present invention during a first stage of fabrication.

FIG. 5 is a top view of a semiconductor device according to an embodiment of the present invention during a further stage of fabrication.

FIG. 6 is a top view of a semiconductor device during a further stage of fabrication including support balls according to an embodiment of the present invention.

FIG. 7 is a side view of a semiconductor device during the stage of fabrication shown in FIG. 6 including support balls according to an embodiment of the present invention.

FIG. 8 is a side view of a semiconductor device according to an embodiment of the present invention during a further stage of fabrication.

FIG. 9 is a side view of a completed semiconductor device according to an embodiment of the present invention.

FIG. 10 is a top view of a semiconductor device according to an embodiment of the present invention during a first stage of fabrication.

FIG. 11 is a top view of a semiconductor device according to an embodiment of the present invention during a further stage of fabrication.

FIG. 12 is a top view of a semiconductor device during a further stage of fabrication including a support loop according to an embodiment of the present invention.

FIG. 13 is a side view of a semiconductor device during a stage of fabrication including a support loop shown in FIG. 12.

FIG. 14 is a side view of a semiconductor device according to an embodiment of the present invention during a further stage of fabrication.

FIG. 15 is a side view of a completed semiconductor device according to an alternative embodiment of the present invention.

### DETAILED DESCRIPTION

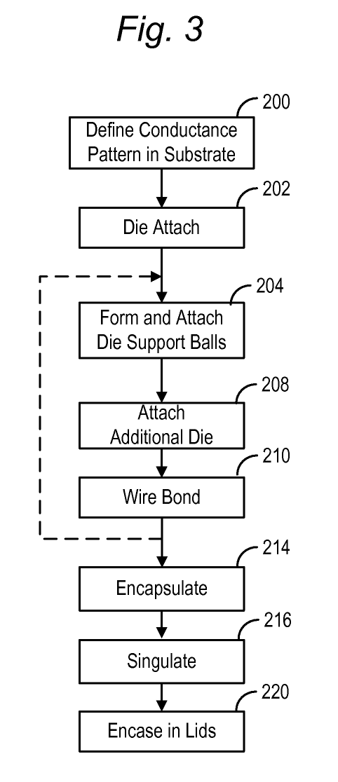

Embodiments will now be described with reference to FIGS. 3 through 15, which relate to a semiconductor package and methods of forming same. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom” and “upper” and “lower” are used herein for convenience and illustrative purposes only, and are not meant to limit the description of the invention inasmuch as the referenced item can be exchanged in position.

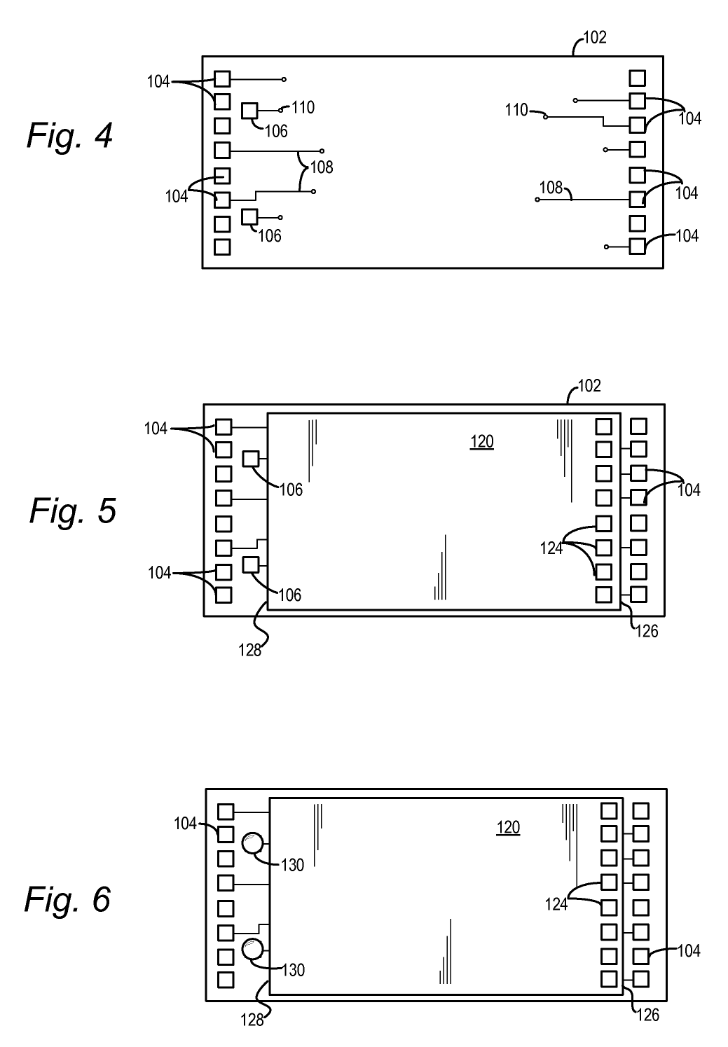

A process for forming a semiconductor package 100 in accordance with the present invention will now be explained with reference to the flowchart of FIG. 3, and the various top and side views of FIGS. 4 through 15. Referring initially to the top view of FIG. 4, there is shown a substrate 102. Although not shown, substrate 102 may be part of a panel of substrates so that the semiconductor packages according to the present invention may be batch processed for economies of scale. Although fabrication of a single semiconductor package is described below, it is understood that the following description may apply to all packages formed on the substrate panel.

The substrate 102 may be a variety of different chip carrier mediums, including a PCB, a leadframe or a tape automated bonded (TAB) tape. Where substrate 102 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like. The conductive layers may be formed of copper or copper alloys, plated copper or plated copper alloys, Alloy 42 (42Fe/58Ni), copper plated steel or other metals or materials known for use on substrates.

The conductive layers may be etched into a conductance pattern in a step 200 as is known. The conductance pattern communicates signals between semiconductor die (affixed to the substrate as explained hereinafter) and an external device (not shown). The conductance pattern may include contact pads 104, 106 and electrical traces 108. The number and pattern of contact pads and electrical traces shown is by way of example in the figures, and there may be many more contact pads and electrical traces, in a variety of patterns, in further embodiments. In the embodiment of FIG. 4, the contact pads 106 are not aligned with any particular contact pad 104. The two pads 106 shown in FIG. 4 may align with two pads 104 in alternative embodiments. Where the semiconductor package is a land grid array (LGA) package, contact fingers (not shown) may also be defined on a back surface of the substrate 102. Vias 110 are provided for communicating signals between the front and back surfaces of the substrate 102. Portions of the upper and lower surfaces of the substrate 102 may be covered with a layer of solder mask, leaving the contact pads 104, 106 and the contact fingers (if provided) exposed. The contact pads 104, 106 and the contact fingers (if provided) may then be plated with one or more gold layers, for example in an electroplating process as is known in the art.

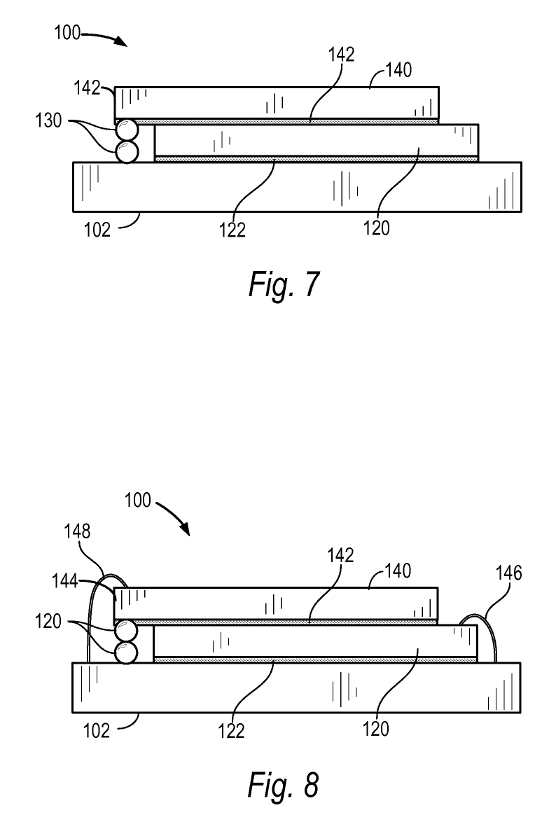

Referring now to the top view of FIG. 5, a semiconductor die 120 may be mounted to substrate 102 in step 202. The die 120 may be affixed to substrate 102 via a die attach adhesive 122 (FIG. 7) in a known adhesive or eutectic die bond process. The die includes a plurality of die bond pads 124 adjacent a first edge 126 of die 120. After die 120 is mounted, the contact pads 104 and 106 on substrate 102 remain exposed adjacent a second edge 128 of die 120.

Referring now to the top view of FIG. 6, in accordance with the present invention, die support balls 130 may be affixed to contact pads 106 in a step 204. FIG. 6 shows support balls 130 at two positions along the edge 128 of die 120. It is understood that the support balls 130 may be provided at a single position or at more than two positions along edge 128 of die 120 in alternative embodiments. Referring now to the side view of FIG. 7 in addition to the top view of FIG. 6, a pair of support balls 130 may be stacked one atop another at each position having support balls.

In embodiments, the support balls 130 may be formed on substrate 102 using a conventional wire bonding capillary (not shown). For example, in one embodiment, support balls 130 may be deposited by forming a ball at the tip of the capillary via a transducer associated with the capillary. The size of the ball 130 may be controlled by the capillary, depending on the number of balls 130 to be included in a single stack, and the thickness of semiconductor die 120. The capillary may then be lowered to a contact pad 106. The surface of substrate 102 may or may not be heated to facilitate bonding of support balls 130 to contact pads 106. After a ball 130 is formed, the ball 130 may then be deposited on a contact pad 106 under a load, while the transducer applies ultrasonic energy. The combined heat, pressure, and/or ultrasonic energy create a bond between the support ball 130 and the contact pad 106. The wire bonding device may then pay out a small length of wire, and the wire may be severed at the support ball to leave the support ball on the contact pad. The small tail of wire hanging from the end of the capillary may then be used to form the next support ball 130. The next support ball 130 may be stacked directly on top of the first support ball 130. Alternatively, the first level of support balls 130 may be formed on all contact pads 106 before a second level of support balls 130 is stacked on the first level.

Support balls 130 may be formed at the bond pads 106 of substrate 102 by a variety of other methods including for example stud bumping or gold bumping at the wafer or assembly level, or a combination of any of the above-described balls and bumps. Moreover, the size and shape of support balls 130 may vary in alternative embodiments of the present invention. In embodiments, support balls 130 may each be spherical, ovoid having a length greater than its width or ovoid having a width greater than its length. Such shapes may be formed in a known manner when a wire at the tip of the capillary is melted and then applied to a bond pad in a ball bonding process. It is understood that support balls 130 may be other shapes in further embodiments of the present invention. Moreover, while a stack of support balls is shown having two support balls, it is understood that a single location may include a single support ball or more than two support balls in further embodiments. This may be determined in part by the thickness of the semiconductor die 120 used.

Having a shape as described in any of the embodiments above, stacked support balls 130 as shown in FIG. 7 may extend above the substrate 102 to a height which is approximately equal to the thickness of a semiconductor die 120. In embodiments, the height of a support ball 130 may be a few hundred microns to 5-10 mils, depending in part on a thickness of the semiconductor die used, and the configuration of the wire bonding capillary used. It is understood that the height of support balls 130 may be less than a few hundred microns and greater than 10 mils in alternative embodiments of the present invention. Moreover, where a stack contains two or more support balls 130, it is understood that each ball in a stack may be the same diameter or may have different diameters from each other.

Referring still to FIG. 7, in step 208 an additional die, die 140 in FIG. 7, may be affixed on the die stack. The die 140 may be affixed to substrate 102 via a die attach adhesive 142 in a known adhesive or eutectic die bond process. The die includes a plurality of die bond pads (not seen in the side view of FIG. 7) adjacent an edge 144 of die 140. In embodiments (not shown), an interposer layer as is known in the art may additionally be included between die 120 and die 140. As an interposer layer would effectively raise the height of the second die 140 above the surface of the first die 120, the height of the support balls 130 may be increased accordingly.

As seen in FIG. 7, the height of the balls 130 is approximately the thickness of the first semiconductor die 120 so that the second semiconductor die 140 rests flatly on both the first semiconductor die 120 and the support balls 130. To the extent engineering tolerances prevent precise sizing of the height of the support ball stack, the height may vary to the thickness of the die attach adhesive 142. Thus, the height of the stacked support balls may be slightly greater than the thickness of the first die 120, in which case the upper support ball 130 may project into the die attach adhesive 142 on the underside of die 140. Moreover, if the height of the stacked support balls is slightly greater than the thickness of the first die 120, the height of the support balls may be reduced by the downward force with which the second die 140 is mounted on the die stack during the die attach process.

As the support balls 130 are conductive and are in contact with both contact pads 106 and the underside of die 140, the contact pads 106 may be electrically grounded pads. Thus, electrically shorting is prevented. It is understood that a layer of dielectric may be provided on the underside of die 140 instead of or in addition to adhesive die attach layer 142. In such embodiments, contact pads 106 need not be grounded pads.

After semiconductor die 140 is affixed to the die stack in step 208, wire bonds may electrically couple the die 120, 140 to the substrate 102 in step 210. In particular, as shown in the side view of FIG. 8, wire bonds 146 may be attached between die bond pads on die 120 and contact pads 104 on substrate 102, and the wire bonds 148 may be attached between die bond pads on die 140 and contact pads 104 on substrate 102. The wire bonds 146, 148 may be formed in a known wire bond process such as for example forward or reverse ball bonding.

As explained in the Background section, in prior art packages where edge 144 of the upper die 140 is not supported, pressure exerted on that edge of the die 140 by the wire bonding capillary during the wire bonding process may damage the die 140. However, owing to the support of the support balls 130, damage to the die 140 during the wire bonding process is prevented.

The embodiment shown in FIG. 8 includes two stacked die. However, it is understood that more than two semiconductor die may be included in the die stack. Accordingly, as indicated by the dashed arrow in the flowchart of FIG. 3, the step 204 of forming and attaching support balls, the step 208 of attaching an additional die, and the step 210 of wire bonding the additional die may be repeated one or more additional times. In one example where a third die is added, it may be offset in the opposite direction than die 140 so that the third die is aligned directly over the first die 120. In such an embodiment, the support balls 130 may be provided on one or more of the die bond pads 124 at the first edge 126 of die 120. Additional die may be added in a similar, alternating offset manner.

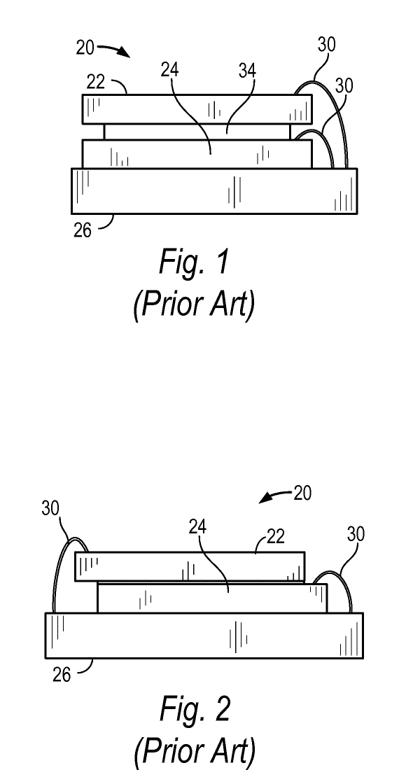

Although the above description has related to adding support balls to a semiconductor package including an offset die stack, it is also contemplated that the support balls may be used to support the overhanging edges in an overlapping die stack such as shown in prior art FIG. 1. In such an embodiment, the support balls may be the same thickness as the spacer layer 34 of the prior art package shown in FIG. 1. The support balls may be provided adjacent the edges of the spacer layer to support the overhanging edges of one or both sides of the upper die.

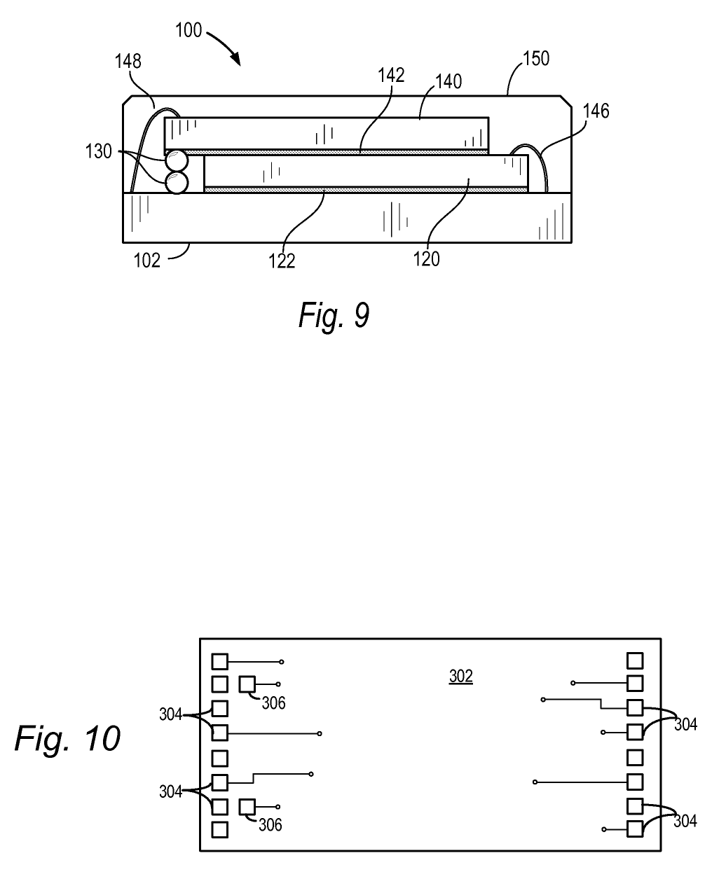

Referring now to the side view of FIG. 9, after the die stack is formed and wire bonded to bond pads on the substrate 102, the die stack may be encased within the molding compound 150 in step 216, and singulated from the panel in step 218, to form a finished semiconductor die package 100. Molding compound 150 may be a known epoxy such as for example available from Sumitomo Corp. and Nitto Denko Corp., both having headquarters in Japan. In some embodiments, the finished package 100 may optionally be enclosed within a lid in step 220.

An alternative embodiment of the present invention will now be described with reference to the top and side views of FIGS. 10 through 15. Components having like structure and operation to that of the above-described embodiment have reference numbers incremented by 200. As shown in FIG. 10, a substrate 302 is provided including contact pads 304, 306 and electrical traces 308 defined therein. In the embodiment of FIG. 10, the contact pads 306 are shown aligned with a pair of contact pads 304. The two pads 306 shown in FIG. 10 need not align with any pads 304 in alternative embodiments.

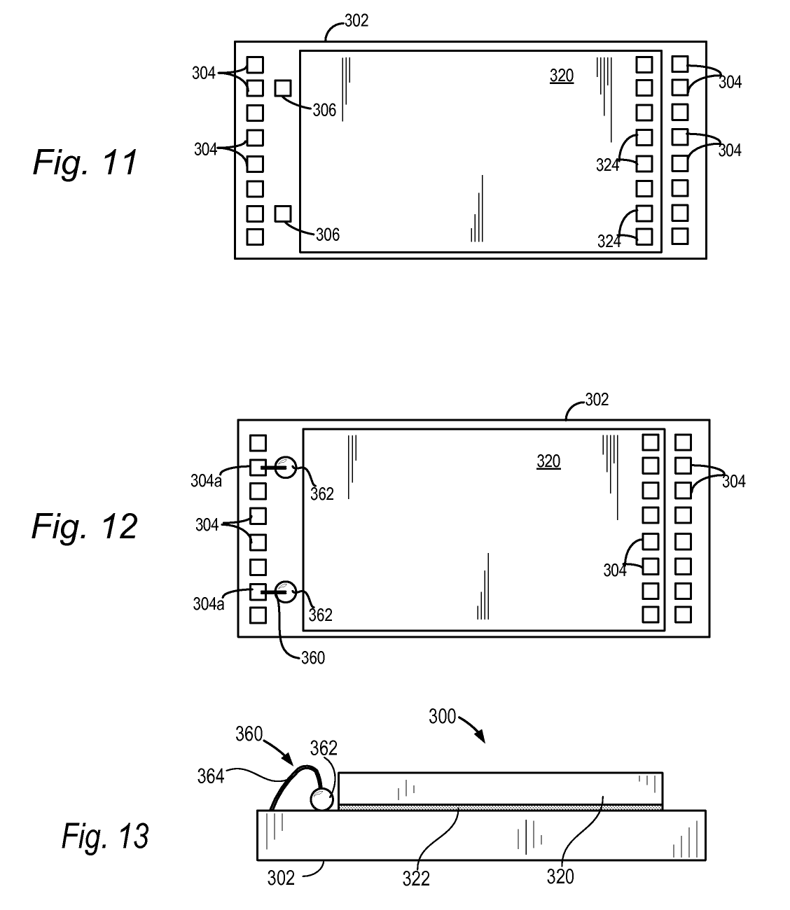

As shown in the top view of FIG. 11, a first semiconductor die 320 including die bond pads 324 may be mounted to the substrate 302 as described above with respect to die 320 using a die attach layer 322 (FIG. 13). In accordance with this embodiment, a wire loop 360, also referred to herein as a balcony loop, is then wire bonded between the bond pads 306 on the substrate, and an adjacent bond pad 304 (304a in FIG. 12) on the substrate 302. The balcony loop 360 is provided by first forming a ball 362 at the tip of the capillary via a transducer associated with the capillary. The capillary may then be lowered to a contact pad 306. The surface of substrate 302 may or may not be heated to facilitate bonding of ball 362 to contact pad 306. After a ball 362 is formed, the ball 362 may then be deposited on a contact pad 306 under a load, while the transducer applies ultrasonic energy. The combined heat, pressure, and/or ultrasonic energy create a bond between the ball 362 and the contact pad 306.

The wire bonding capillary may then pay out a length of wire to form a loop 364, and the capillary moves over to the adjacent contact pad 304. The loop 364 may have a rounded apex, or a flat apex, in different embodiments. A wedge bond or the like is then formed on the adjacent contact pad 304a again using heat, pressure and ultrasonic energy. A small amount of wire is then payed out and the wire is pulled off at the wedge bond.

The wire used to form balcony loop 360 may be the same thickness or thicker and sturdier than the wire used to form the wire bonds described above. In embodiments, the wire used in loop 360 may be 0.8 mils to 1 mil as compared to 0.8 mils for the wire bonds. These thicknesses are by way of example only and may vary in alternative embodiments. While the Figures show two balcony loops 360, it is understood that a single balcony loop may be used or more than two balcony loops may be used.

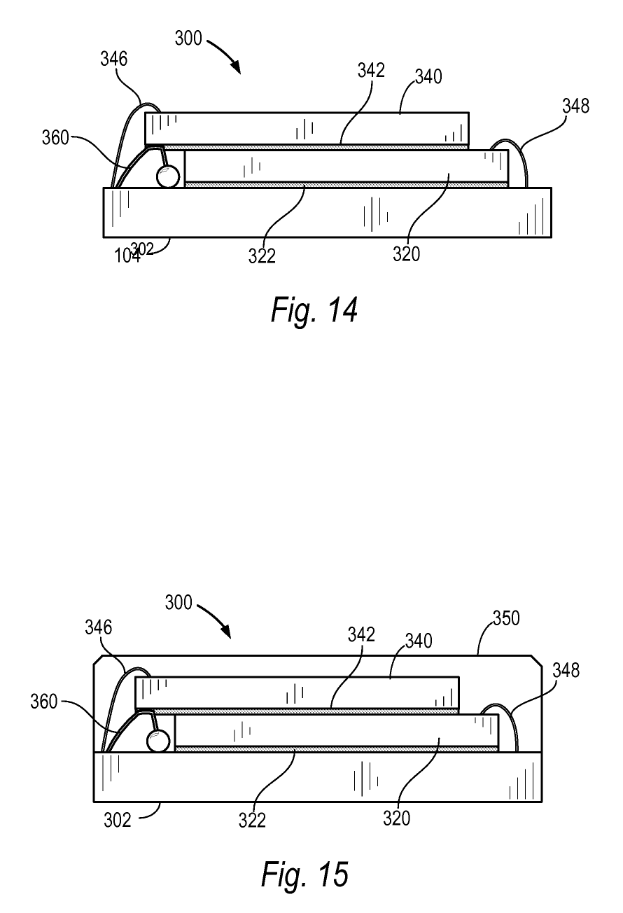

Referring now to the side view of FIG. 14, a second semiconductor die 340 may next be mounted atop the first semiconductor die 320 using an adhesive die attach layer 342. The loop 364 may be slightly compressed by the second die 340 when it is mounted on the die stack, but the balcony loop 360 provides structural support for overhanging edge 344 of die 340. This structural support is sufficient to withstand the pressure exerted on edge 344 during the subsequent wire bonding process. As the balcony loop 360 is conductive and is in contact with both contact pads 304a, 306 and the underside of die 340, the contact pads 304a and 306 may be electrically grounded pads. Thus, electrical shorting is prevented. It is understood that a layer of dielectric may be provided on the underside of die 340 instead of or in addition to adhesive die attach layer 342. In such embodiments, contact pads 304a and 306 need not be grounded pads.

As is further shown in FIG. 14, after mounting the second die 340, wire bonds 346 and 348 may electrically couple the die 320, 340 to the substrate 302 as described above for wire bonds 146 and 148. The wire bonds 346, 348 may be formed in a known wire bond process such as for example forward or reverse ball bonding. The bond pad(s) 304a receiving an end of balcony loop 360 may or may not also receive an end of wire bond 346. The balcony loop 360 provides support to the edge 344 of die 340 to prevent damage to the die 340 when wire bonds 348 are formed. As described above with respect to the support ball 130 embodiments, more than two semiconductor die may be affixed to the die stack in this embodiment by forming one or more balcony loops 360 at each level of the die stack.

Referring now to the side view of FIG. 15, after the die stack is formed and wire bonded to bond pads on the substrate 302, the die stack may be encased within the molding compound 350, and singulated from the panel to form a finished semiconductor die package 300. In some embodiments, the finished package 300 may optionally be enclosed within a lid.

In embodiments, the semiconductor die 120, 140 used within package 100/300 may include one or more flash memory chips, and possibly a controller such as an ASIC, so that the package 100/300 may be used as a flash memory device. It is understood that the package 100/300 may include semiconductor die configured to perform other functions in further embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a first component including a plurality of contact pads;
a second component supported over the first component, the second component including an edge not supported by the first component and positioned over a portion of contact pads of the plurality of contact pads on the first component;
a support structure affixed to one or more contact pads of the portion of contact pads on the first component, the support structure supporting the edge of the second component not supported by the first component; and
at least one wire bond extending from a die bond pad on the second component, at the edge of the second component not supported by the first component, for electrically coupling the second component to the semiconductor device.

2. The semiconductor device of claim 1, wherein the first component comprises a substrate and the second component comprises a second semiconductor die mounted on a first semiconductor die, the first semiconductor die mounted on the substrate.

3. The semiconductor device of claim 1, wherein the first component comprises a first semiconductor die and the second component comprises a second semiconductor die mounted on a spacer layer, the spacer layer mounted on the first semiconductor die.

4. The semiconductor device of claim 1, wherein the support structure comprises one or more balls deposited on the first component.

5. The semiconductor device of claim 1, wherein the support structure comprises one or more stacks of balls deposited on the first component.

6. The semiconductor device of claim 1, wherein the support structure comprises a wire loop formed between a pair of contact pads of the portion of contact pads on the first component.

7. The semiconductor device of claim 1, wherein the support structure is affixed to the one or more contact pads by a wire bonding capillary.

8. The semiconductor device of claim 1, wherein the support structure is formed on the one or more contact pads by one of stud bumping or gold bumping at the wafer level.

9. The semiconductor device of claim 1, wherein the one or more contact pads to which the support structure is affixed are electrically grounded.

10. The semiconductor device of claim 1, further comprising a dielectric layer on an underside of the second semiconductor die.

11. The semiconductor device of claim 10, wherein the one or more contact pads to which the support structure is affixed are not electrically grounded.

12. The semiconductor device of claim 1, wherein the device is a flash memory device.

13. A semiconductor device, comprising:
a substrate including a plurality of contact pads;
a first semiconductor die mounted on a surface of the substrate, at least a portion of the contact pads on the substrate exposed next to a first edge of the first semiconductor die;
a second semiconductor die mounted on a surface of the first semiconductor die, the second semiconductor die including a first edge not supported by the first semiconductor die;
a support structure affixed to one or more contact pads of the portion of contact pads on the substrate exposed next to the first edge of the first semiconductor die, the support structure supporting the first edge of the second semiconductor die not supported by the first semiconductor die; and
at least one wire bond affixed between a die bond pad on the second semiconductor die and a contact pad of the plurality of contact pads on the substrate.

14. The semiconductor device of claim 13, wherein the support structure comprises one or more balls deposited on the substrate.

15. The semiconductor device of claim 13, wherein the support structure comprises one or more stacks of balls deposited on the substrate.

16. The semiconductor device of claim 13, wherein the support structure comprises a wire loop formed between a pair of contact pads of the portion of contact pads on the substrate.

17. The semiconductor device of claim 13, wherein the one or more contact pads to which the support structure is affixed are electrically grounded.

18. The semiconductor device of claim 13, further comprising a dielectric layer on an underside of the second semiconductor die.

19. The semiconductor device of claim 18, wherein the one or more contact pads to which the support structure is affixed are not electrically grounded.

20. A semiconductor device, comprising:
a substrate including a plurality of contact pads;
a first semiconductor die mounted on a surface of the substrate;
a second semiconductor die mounted on a surface of the first semiconductor die, the second semiconductor die including a first edge not supported by the first semiconductor die;
one or more support balls mounted to one or more contact pads of the plurality of contact pads on the substrate, the support balls supporting the first edge of the second semiconductor die not supported by the first semiconductor die; and
at least one wire bond affixed between a die bond pad on the second semiconductor die and a contact pad of the plurality of contact pads on the substrate.

21. The semiconductor device of claim 20, wherein the one or more support balls comprise a stack of support balls on a single contact pad of the one or more contact pads.

22. The semiconductor device of claim 20, wherein the one or more contact pads to which the one or more support balls are affixed are electrically grounded.

23. The semiconductor device of claim 20, wherein the one or more support balls are affixed to the one or more contact pads by a wire bonding capillary.

24. The semiconductor device of claim 20, wherein the one or more support balls are formed on the one or more contact pads by one of stud bumping or gold bumping at the wafer level.

25. A semiconductor device, comprising:
a substrate including a plurality of contact pads;
a first semiconductor die mounted on a surface of the substrate;
a second semiconductor die mounted on a surface of the first semiconductor die, the second semiconductor die including a first edge not supported by the first semiconductor die;
a wire loop mounted between a pair of contact pads of the plurality of contact pads on the substrate, the wire loop supporting the first edge of the second semiconductor die not supported by the first semiconductor die; and
at least one wire bond affixed between a die bond pad on the second semiconductor die and a contact pad of the plurality of contact pads on the substrate.

26. The semiconductor device of claim 25, wherein the pair of contact pads to which the wire loop is affixed are electrically grounded.

27. The semiconductor device of claim 25, wherein the wire loop is affixed to the pair of contact pads by a wire bonding capillary.

28. The semiconductor device of claim 25, wherein wire for the wire loop is thicker than wire for the wire bond.

29. The semiconductor device of claim 25, wherein wire for the wire loop is the same diameter as wire for the wire bond.

30. The semiconductor device of claim 25, wherein a contact pad of the pair of contact pads receiving the wire loop is the same contact pad of the at least one contact pad receiving a wire bond.
